(19) United States
(12) Patent Application Publication
(10) Pub. No.: US 2012/0152310 A1
(43) Pub. Date: Jun. 21, 2012

(54) STRUCTURALLY BREAKING UP A SOLAR ARRAY OF A TWO-AXIS TRACKER ASSEMBLY IN A CONCENTRATED PHOTOVOLTAIC SYSTEM

(75) Inventors: Brian Hinman, Los Gatos, CA (US); Wayne Miller, Los Altos, CA (US)

(73) Assignee: GREENVOLTS, INC., Fremont, CA (US)

(21) Appl. No.: 13/227,656

(22) Filed: Sep. 8, 2011

Related U.S. Application Data
(60) Provisional application No. 61/424,537, filed on Dec. 17, 2010.
(60) Provisional application No. 61/424,515, filed on Dec. 17, 2010.
(60) Provisional application No. 61/424,493, filed on Dec. 17, 2010.
(60) Provisional application No. 61/424,518, filed on Dec. 17, 2010.

(51) Int. Cl. H01L 31/052; H01L 31/18

(52) U.S. Cl. 136/246; 29/890.033

(57) ABSTRACT

In an embodiment, a solar array has its surface area structurally broken up into multiple discreet components smaller in size than the entire solar array itself. Multiple paddle pair assemblies form and make up the surface area of the solar array. Two or more of the paddle structures form a paddle pair assembly per tilt axle of the two axis tracker mechanism. A set of solar receivers, each with its own secondary concentrator optic is aligned within and secured in place in each CPV module in a paddle structure. All of the photovoltaic cells on the two axis tracker mechanism are electrically connected to form the voltage output from the solar array.

### RELATED APPLICATIONS

This application is a continuation in part of and claims the benefit of and priority to U.S. Provisional Application titled “Integrated electronics system” filed on Dec. 17, 2010 having application Ser. No. 61/424,537, U.S. Provisional Application titled “Two axis tracker and tracker calibration” filed on Dec. 17, 2010 having application Ser. No. 61/424,515, U.S. Provisional Application titled “ISIS AND WIFI” filed on Dec. 17, 2010 having application Ser. No. 61/424,493, and U.S. Provisional Application titled “Photovoltaic cells and paddles” filed on Dec. 17, 2010 having application Ser. No. 61/424,518.

### NOTICE OF COPYRIGHT

A portion of the disclosure of this patent document contains material that is subject to copyright protection. The copyright owner has no objection to the facsimile reproduction by anyone of the interconnect as it appears in the Patent and Trademark Office Patent file or records, but otherwise reserves all copyright rights whatsoever.

### FIELD

In general, a photovoltaic system having a two-axis tracker assembly for a photovoltaic system is discussed.

### BACKGROUND

A two-axis tracker may break up its solar array for more efficient operation. A two axis tracker may be designed for easier of installation in the field.

### SUMMARY

Various methods and apparatus are described for a photovoltaic system. In an embodiment, the solar array has a surface area of the solar array structurally broken up into multiple discreet components smaller in size than the entire solar array itself. One or more concentrated photovoltaic modules are aligned within and secured in place in each paddle structure. Multiple paddle pair assemblies exist per common roll axle of the two axis tracker mechanism. The paddle pair assemblies form and make up the surface area of the solar array. Two or more of the paddle structures form a paddle pair assembly per tilt axle of the two axis tracker mechanism. Each tilt axle is independently movable from another tilt axle connected to the common roll axle. A set of solar receivers, each with its own secondary concentrator optic is aligned within and secured in place in each CPV module. The secondary concentrator optic focuses light onto a photovoltaic cell. All of the photovoltaic cells on the two axis tracker mechanism are electrically connected to form the voltage output from the solar array.

### BRIEF DESCRIPTION OF THE DRAWINGS

The multiple drawings refer to the embodiments of the invention.

FIGS. 1A and 1B illustrate diagrams of an embodiment of a two axis tracking mechanism for a concentrated photovoltaic system having multiple independently movable sets of concentrated photovoltaic solar (CPV) cells.

FIG. 2 illustrates a diagram of one or more modules aligned within and secured in place in a paddle structure.

FIG. 3 illustrating a diagram of a side perspective of an embodiment of the frame of two paddle structures structurally locked together via the mechanical interface.

FIG. 4 illustrates an exploded view of an embodiment of a skeletal frame of the paddle structure coupling to multiple modules.

FIG. 5 illustrates an exploded view of a diagram of an embodiment of a module that has a grid of Fresnel lenses covering each set of solar receivers, a patterned panel of Fresnel lenses, and output leads.

FIGS. 6A and 6B illustrate diagrams of an embodiment of a Fresnel lens optically coupling to the solar receiver.

FIGS. 7A and 7B illustrate diagrams of embodiments of a total internal reflection prism having a domed shaped top portion and trapezoidal bottom portion that is used as a secondary concentrating mirror surface for the multiple junction photovoltaic cell.

FIG. 8 illustrates a block diagram of an embodiment of the physical and electrical arrangement of modules in a representative two axis tracker assembly.

FIG. 9 illustrates a diagram of an embodiment of a paddle structure generating DC voltage by the CPV cells supplying power to an inverter power circuitry and is specifically designed to supply an input voltage range anticipated from the fixed number of photovoltaic cells.

FIG. 10 illustrates a schematic diagram of an embodiment of a first AC inverter circuit and a second AC inverter circuit combining to supply the Utility Power grid transformer.

FIGS. 11A and 11B illustrate diagrams of an embodiment of paddle structures having a designed shape and dimension of the paddle structures loaded with one or modules to fit into a standard sized shipping container.

While the invention is subject to various modifications and alternative forms, specific embodiments thereof have been shown by way of example in the drawings and will herein be described in detail. The invention should be understood to not be limited to the particular forms disclosed, but on the contrary, the intention is to cover all modifications, equivalents, and alternatives falling within the spirit and scope of the invention.

### DETAILED DISCUSSION

In the following description, numerous specific details are set forth, such as examples of specific cells, named components, connections, types of connections, etc., in order to provide a thorough understanding of the present invention. It will be apparent, however, to one skilled in the art that the present invention may be practiced without these specific details. In other instances, well known components or methods have not been described in detail but rather in a block diagram in order to avoid unnecessarily obscuring the present invention. Further specific numeric references such as a first paddle, may be made. However, the specific numeric reference should not be interpreted as a literal sequential order but rather interpreted that the first paddle is different than a second paddle. Thus, the specific details set forth are merely exemplary. The specific details may be varied from and still be contemplated to be within the spirit and scope of the present invention.

In general, various methods and apparatus are discussed for a photovoltaic system. The components of the solar array are structurally broken up from a single array into smaller, for example, two Kilowatt modules housed in a paddle structure format that are easier to fabricate, assemble and maintain these component parts. Further, structurally creating multiple smaller solar powered generating units verses one large solar array, takes advantage of economy of scale, better pointing accuracy, lower cost as well as other advantages. In an embodiment, the solar array has a surface area of the solar array structurally broken up into multiple discreet components smaller in size than the entire solar array itself. One or more concentrated photovoltaic modules are aligned within and secured in place in each paddle structure. Multiple paddle pair assemblies exist per common roll axle of the two axis tracker mechanism. The paddle pair assemblies form and make up the surface area of the solar array. Two or more of the paddle structures form a paddle pair assembly per tilt axle of the two axis tracker mechanism. Each tilt axle is independently movable from another tilt axle connected to the common roll axle. A set of solar receivers, each with its own secondary concentrator optic is aligned within and secured in place in each CPV module. The secondary concentrator optic focuses light onto a photovoltaic cell. All of the photovoltaic cells on the two axis tracker mechanism are electrically connected to form the voltage output from the solar array.

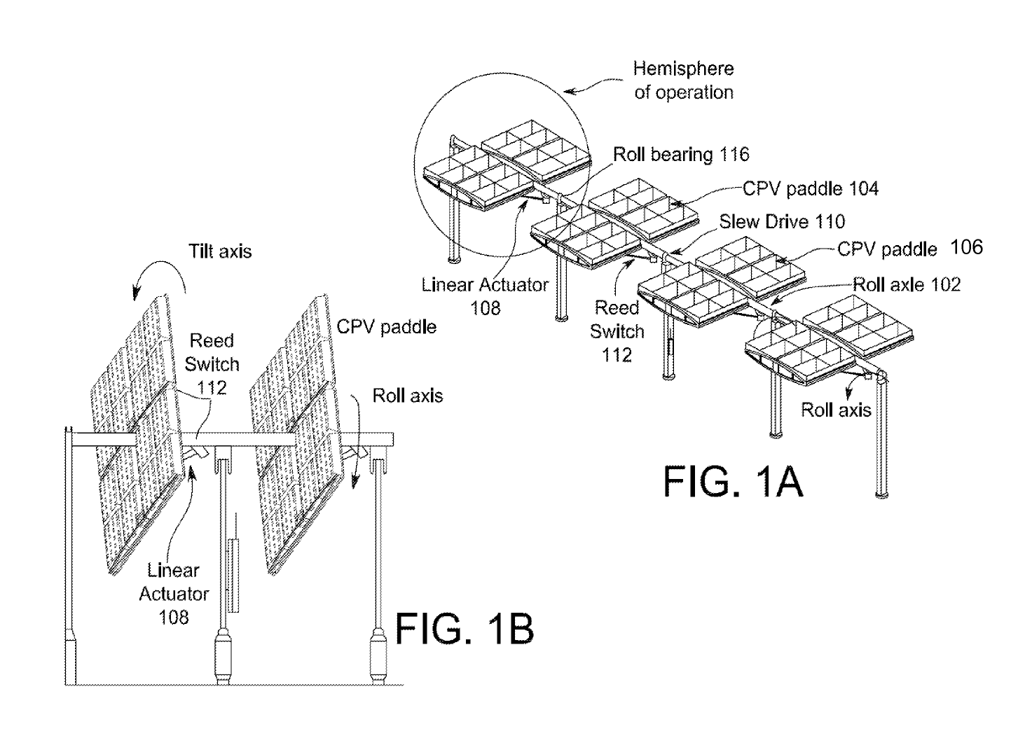

FIGS. 1A and 1B illustrate diagrams of an embodiment of a two axis tracking mechanism for a concentrated photovoltaic system having multiple independently movable sets of concentrated photovoltaic solar (CPV) cells. FIG. 1A shows the paddle assemblies containing the CPV cells, such as four paddle assemblies, at a horizontal position with respect to the common roll axle. FIG. 1B shows the paddle assemblies containing the CPV cells tilted up vertically by the linear actuators with respect to the common roll axle. The surface area of the solar array is structurally broken up into multiple discreet components, such as discrete paddle structures, smaller in size than entire solar array itself. The multiple sets of paddle pair assemblies per common roll axle of the two axis tracker mechanism form and make up the surface area of the solar array. Each 16 Kilowatt (KW) CPV power array is structurally broken up from a single power array into an example number of four paddle pair assemblies.

A common roll axle 102 is located between 1) stanchions, and 2) multiple CPV paddle assemblies. Each of the multiple paddle assemblies, such as a first paddle assembly 104, contains its own set of the CPV solar cells contained within that CPV paddle assembly that is independently movable from other sets of CPV cells, such as those in the second paddle assembly 106, on that two axis tracking mechanism. Each paddle assembly is independently moveable on its own tilt axis and has its own drive mechanism for that tilt axle. The drive mechanism may be a linear actuator with a brushed DC motor. One or more CPV modules may be aligned within and secured in place in each paddle structure. An example number of twenty-four CPV cells may exist per module, with eight modules per CPV paddle, two CPV paddles per paddle assembly, a paddle assembly per tilt axis, and four independently-controlled tilt axes per common roll axis. A set of solar receivers each with its own secondary concentrator optic that is aligned within and secured in place in each module. Each secondary concentrator optic focuses incident light onto its photovoltaic cell. All of the photovoltaic cells on the two axis tracker mechanism are electrically connected to form the DC voltage output from the solar array.

Two or more of the paddle structures form a paddle pair per tilt axle of the two axis tracker mechanism and each tilt axle is independently movable from another tilt axle connected to the common roll axle. Each paddle pair assembly has its own tilt axis linear actuator, such as a first linear actuator 108, for its drive mechanism to allow independent movement and optimization of that paddle pair with respect to other paddle pairs in the two-axis tracker mechanism. Each tilt-axle pivots perpendicular to the common roll axle 102. The common roll axle 102 includes two or more sections of roll beams that couple to the slew drive motor 110 and then the roll beams couple with a roll bearing assembly having pin holes for maintaining the roll axis alignment of the solar two-axis tracker mechanism at the other ends, to form a common roll axle 102. The slew drive motor 110 and roll bearing assemblies are supported directly on the stanchions. A motor control board in the integrated electronics housing on the solar tracker causes the linear tilt actuators and slew drive motor 110 to combine to move each paddle assembly and its CPV cells within to any angle in that paddle assembly's hemisphere of operation. Each paddle assembly rotates on its own tilt axis and the paddle assemblies all rotate together in the roll axis on the common roll axle 102.

The tracker circuitry uses primarily the Sun's angle in the sky relative to that solar array to move the angle of the paddles to the proper position to achieve maximum irradiance. A hybrid algorithm determines the known location of the Sun relative to that solar array via parameters including time of the day, geographical location, and time of the year supplied from a local GPS unit on the tracker, or other similar source. The two-axis tracker tracks the Sun based on the continuous latitude and longitude feed from the GPS and a continuous time and date feed. The hybrid algorithm will also make fine tune adjustments of the positioning of the modules in the paddles by periodically analyzing the power (I-V) curves coming out of the electrical power output circuits to maximize the power coming out that solar tracker.

The hybrid solar tracking algorithm supplies guidance to the motor control board for the slew drive and tilt actuators to control the movement of the two-axis solar tracker mechanism. The hybrid solar tracking algorithm uses both 1) an Ephemeris calculation and 2) an offset value from a matrix to determine the angular coordinates for the CPV cells contained in the two-axis solar tracker mechanism to be moved to in order to achieve a highest power out of the CPV cells. The motion control circuit is configured to move the CPV cells to the determined angular coordinates resulting from the offset value being applied to the results of the Ephemeris calculation.

Note, optimally tracking the Sun with four independently moveable paddle pair assemblies on a solar array is easier and more accurate across the four paddle pairs than with a single large array occupying approximately the same amount of area as the four arrays. In an example, four or more paddles, each contains a set of CPV cells, and form a part of the two-axis solar tracker mechanism. Each of these paddles may be part of a paddle pair assembly that rotates on its own tilt axis. For example, both a first paddle structure containing CPV cells on a first section of a first tilt axle and a second paddle structure containing CPV cells on a second section of the first tilt axle rotate on the axis of that first tilt axle. Likewise, both a third paddle structure containing CPV cells on a first section of a second tilt axle and a fourth paddle structure containing CPV cells on a second section of the second tilt axle rotate on the axis of that second tilt axle. In addition, both the first and second tilt axles connect perpendicular to the common roll axle that universally rotates all of the tilt axles.

Each paddle pair assembly is driven by its tilt drive mechanism to be moved to its ideal angular coordinates in the tilt axis independent of a neighboring paddle assembly that is driven by its tilt drive mechanism to its ideal angular coordinates in the tilt axis. These paddle pair assemblies are all part of the same solar array on the two axis tracker mechanism.

In addition, by breaking the paddle pair assembly into two discrete parts across the common roll axle that move as one unitary larger solar surface area, the wind then has a small space in the middle between the two paddles structures in the paddle pair assembly to pass through and minimize the wind loading effect on the paddle pair assembly. In windier conditions, the paddle pair assembly with the small space in the middle maintains a pointing accuracy of the paddle pair assembly relative to the ideal angular coordinates towards the Sun far better than the unitary larger solar surface area with no space for passing wind in the middle of that solar surface area.

In addition, by locating and coupling the slew drive motor in middle of the common roll axle of the two axis tracker mechanism, then that gives a better overall pointing accuracy to paddle pair assemblies at the ends of the common roll axle because of being closer and more proximate to the slew drive motor than if the slew drive motor was coupled somewhere off-center of the common roll axle. Note, a limited amount, such as four, paddle pairs per tracker creates acceptable twisting torque on the common roll axle to not cause pointing errors or material fatigue on the common roll axle.

An integrated electronics system housing installed on the tracker may include motion control circuits, inverters, ground fault circuits, etc. and act as a local system control point for that solar array.

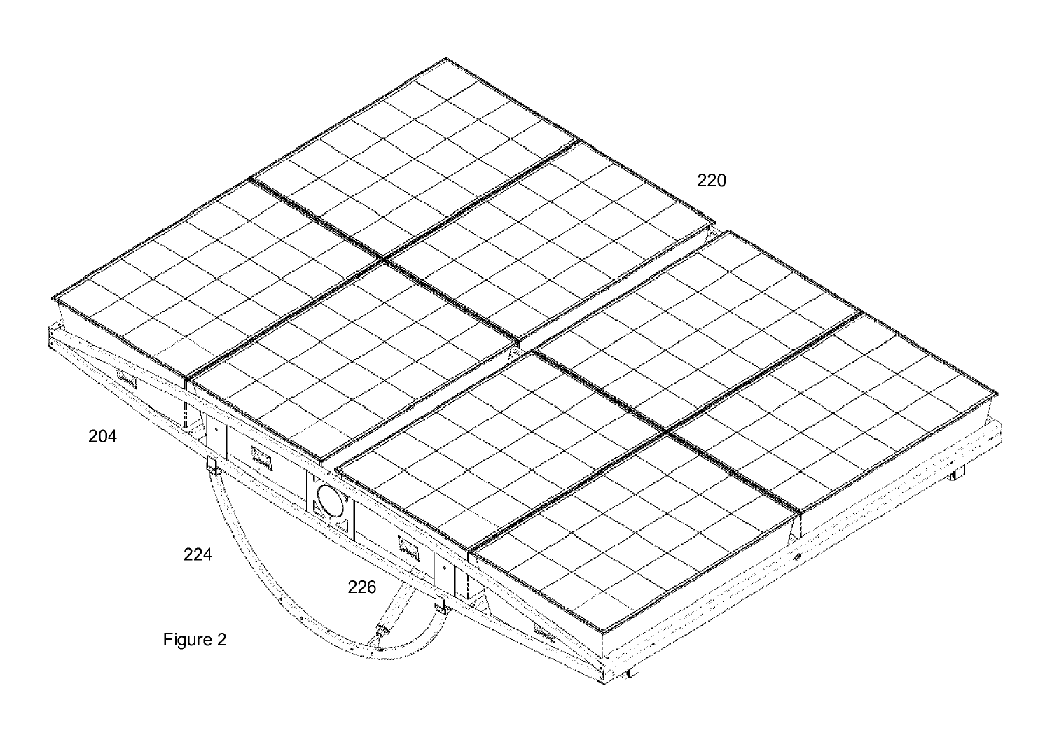

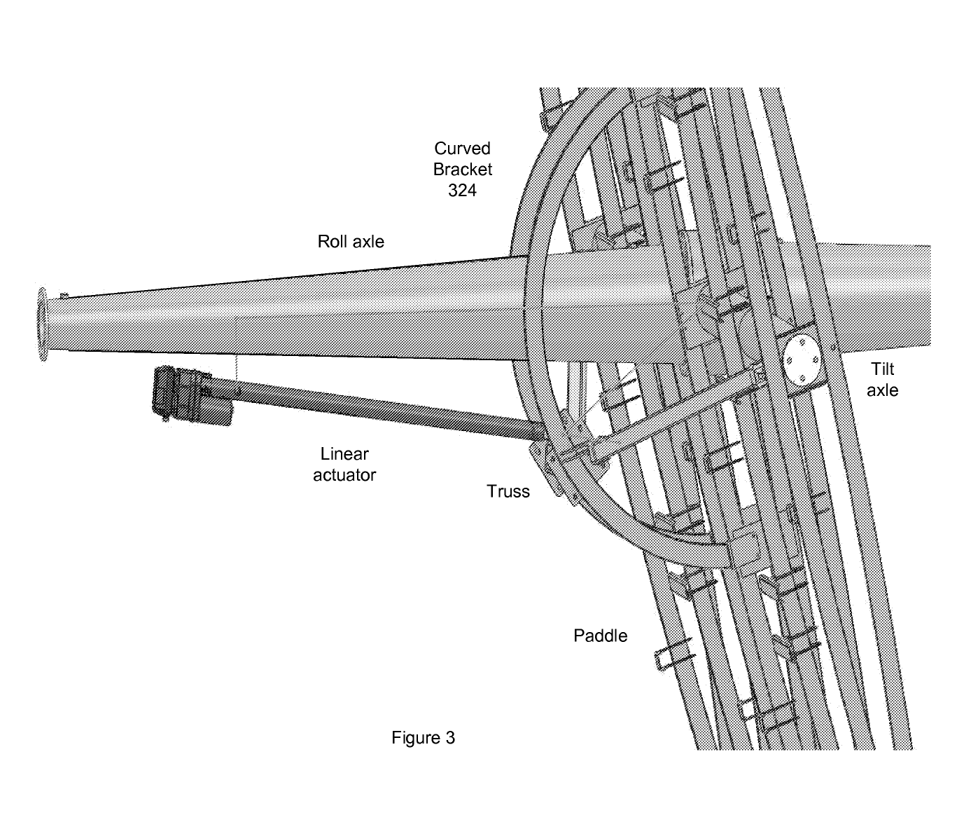

FIG. 2 illustrates a diagram of one or more modules aligned within and secured in place in a paddle structure. Each paddle structure 204 may contain multiple CPV modules 220 as part of the solar array of the two-axis tracking mechanism. The paddle structures have a mechanical interface between each paddle structure 204, such as a curved bracket 224 on each paddle structure 204, a center truss between the brackets, and turnbuckle arms 226 for vertical support to the paddle structure 204 from the center truss, to structurally lock together the paddle structures to form a paddle pair assembly along the tilt axis on a tilt axle on the two sides of the common roll axle. The paddle pair assembly locked together then moves in unison on the tilt axis. See also FIG. 3 illustrating a diagram of a side perspective of the frame of two paddle structures structurally locked together via the mechanical interface. Note two or more paddle structures may form a single paddle assembly.

The shared mechanical interface between paddle structures in paddle pair assembly allows the solar array to be broken up into these multiple smaller paddle structures that are set along the tilt axis on a tilt axle on the two sides of the common roll axle. The smaller paddle structures and shared mechanical interface gives paddle pair assembly a greater accuracy at aiming at the Sun due to 1) having less overall weight to drive the paddle pair assembly and 2) substantially an even amount of weight and wind forces felt on each side of the common roll axle on both paddle structures in the pair. Thus, the weight of the paddle structures on each side of the common roll axle counter balances the paddle pair assembly making the drive motor and linear actuators mainly having to deal with wind loading effects which should roughly be about the same on both sides of the paddle pair assembly. The wind loading force pressing against the surface area of paddle pair assembly should be directed through the frame of the paddle structures and the shared mechanical interface to essentially cancel the wind loading effects from the paddle structures on both sides of the common roll axle.

In addition, the paddle structure's bracket 224 may be curved, triangular, or other shapes. The paddle structure 204 has its bracket 224 on hinges to allow the rapid formation of the paddle assembly on the tilt axle across both sides of the common roll axle in the field. Each hinge allows the bracket 224 to fold flat against its skeletal frame when the paddle structure 204 is shipped and also allows easy maneuverability when assembling the paddle assembly in the field.

The smaller each discrete unit containing solar cells, the easier it is to get each of the CPV solar cells in the entire solar array at a more ideal angle relative to the Sun for that solar cell balanced against the cost of securing and maintaining the solar cells in position during windy conditions. For example, the paddle structure 204 is sized between seven to nine meters squared and preferably around eight meters squared and balanced in size for an amount of steel to support the paddle's weight verses an amount of articulation costs needed to accurately point and then maintain the CPV solar cells contained in that paddle pair assembly at the ideal angle towards the Sun.

As discussed above, by creating structurally multiple smaller solar power generating units, each paddle structure 204 has 1) less steel, 2) less weight, 3) less surface area than if created as a single unitary solar array with the same surface area. As the surface area goes up, it's not a linear function with the steel and weight. With less weight and less surface area, the paddle structure 204 is subject to less bending or bowing across the entire length of the paddle structure 204. The smaller area of paddle structure 204 has less bowing or dipping from end to end across the paddle. Also, the paddle structure 204 has less overall steel costs for the same surface area of cells because the paddle structure 204 need less reinforcement steel to deal with wind loading and bowing. Thus, the paddle structure 204 needs less structural support to secure and maintain the alignment of the CPV cells and CPV module(s) contained in the paddle structure 204 as well as less structural support needed from the shared mechanical interface and other components to resist the wind loading effects to stay in place during high wind conditions, and with less wind loading and lower weight, a lower horsepower drive motor may be used in the two axis tracker to more easily and accurately maintain a pointing accuracy of the paddle structure 204 towards it ideal angular coordinates towards the Sun.

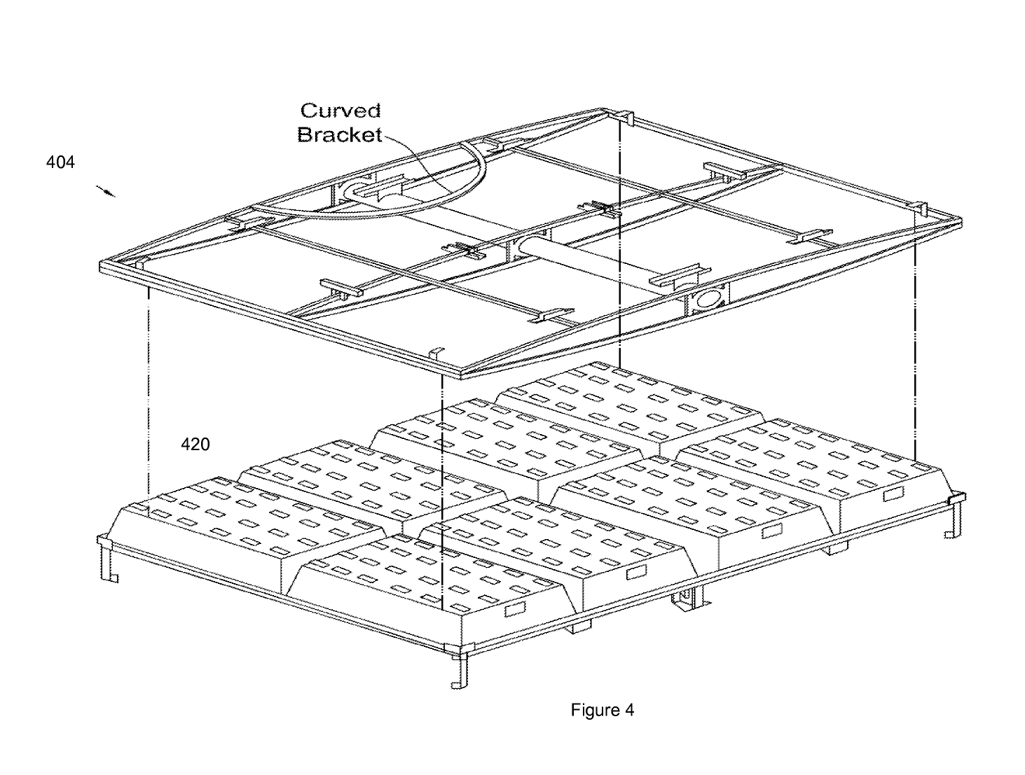

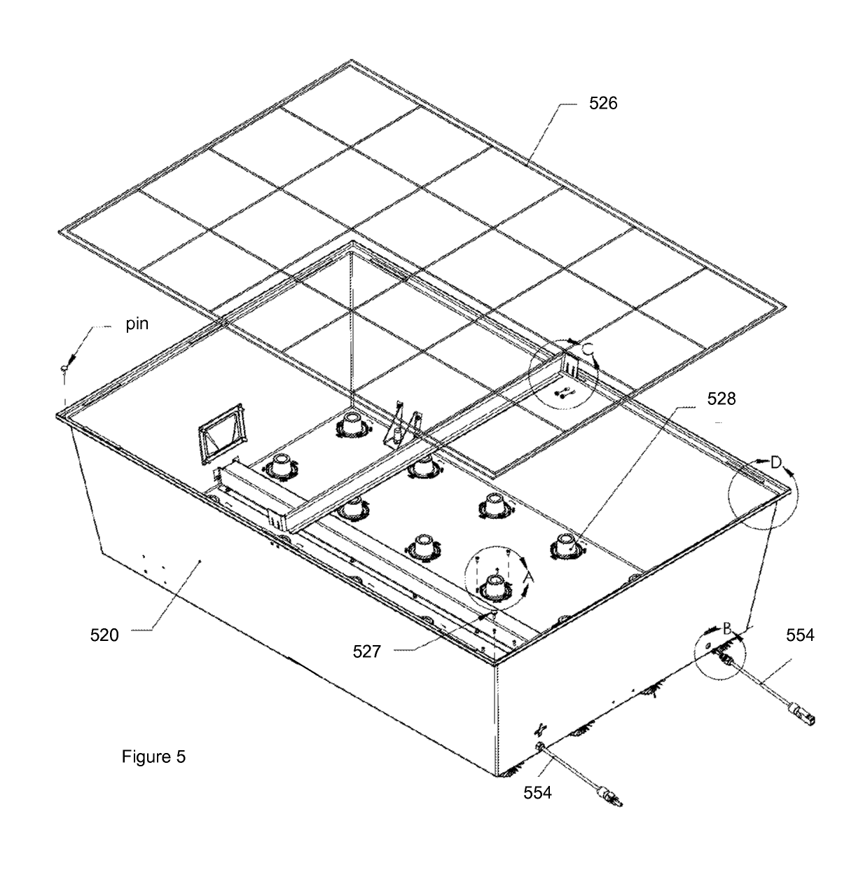

FIG. 4 illustrates an exploded view of an embodiment of a skeletal frame of the paddle structure coupling to multiple modules. Each paddle structure 404 houses at least one of more modules 420. The concentrating photovoltaic system includes rows and columns of photovoltaic cells packaged in the form of a module 420. The solar array broken up into each paddle structure 404 may, for example, contain eight module assemblies integrated together to make a rectangular grid, in which each module contains a fixed number of individual concentrated photovoltaic cells, such as twenty four. Each CPV solar cell is housed in a solar receiver assembly. Multiple solar receiver assemblies are installed also in an evenly spaced grid pattern of columns and rows into each module, and occupy the horizontal surface area of the module. The smaller two Kilowatt modules, housed in a paddle format, are easier to fabricate, assemble, and maintain component parts. The smaller two Kilowatt modules balance factors including thermal requirements for each power generating unit (Fresnel lens and solar receiver assembly), cost of manufacture, power density across the surface of the power array, cost of shipping, and cost of installation to determine the size and amount of component parts in a module. The modules 420 and receivers also take advantage of being manufactured in mass. The modules 420 are massed produced in stamped module templates. Likewise, the components making up the solar receiver are massed produced. Thus, structurally creating multiple smaller solar power generating units that includes multiple CPV receivers installed into stamped module templates in a grid pattern takes advantage of economy of scale, easier to fabricate, assemble and maintain component parts as well as operate more efficiently because each paddle pair assembly containing its set of CPV cells in modules 420 can be more accurately aimed at the Sun independently of how other paddle pairs on that two axis tracker making up the solar array of the tracker can be moved and pointed towards the sun.

The example of 24 receiver assemblies per module and 8 modules per paddle would result in 192 CPV receivers per paddle. 4 CPV paddle pairs (8 paddle structures total) are combined into control of one tracker assembly. A receiver assembly installed into a module coupled with its Fresnel lens generally forms an entire individual power-generating unit. Under the practical effect of economy of scale, making hundreds of identical smaller parts, such as 192 CPV receivers per paddle, is easier and cheaper than manufacturing a single large part. It turns out, the assembly and alignment of all of the CPV receiver assemblies in the modules is easier to assemble and maintain than a single assembly across its entire plane. Further, operationally optimally tracking the Sun with each of the four independently moveable paddle pair assemblies is easier than with a single large array.

FIG. 5 illustrates an exploded view of a diagram of an embodiment of a module that has a grid of Fresnel lenses covering each set of solar receivers, a patterned panel of Fresnel lenses, and output leads. The grid of Fresnel lenses 526 use less material to construct than a normal convex lens and have a wider pointing angle than do conventional mirrors, and covers the module casing. Each solar receiver unit 528, such as a first solar receiver unit 527, contains its own secondary concentrator and its own photovoltaic cell, and optically couples with one of the Fresnel lens in the grid. Multiple solar receiver units 528 may exist per module and share the common grid of Fresnel lenses 526 covering the module housing. The secondary concentrator for the photovoltaic cells in the solar receiver unit has a domed secondary to give a greater acceptance angle for the solar receiver unit. The acceptance angle may be the angle within which incident Sun light on the surface area of the Fresnel lens is totally internally reflected by the secondary concentrator to the photovoltaic cell.

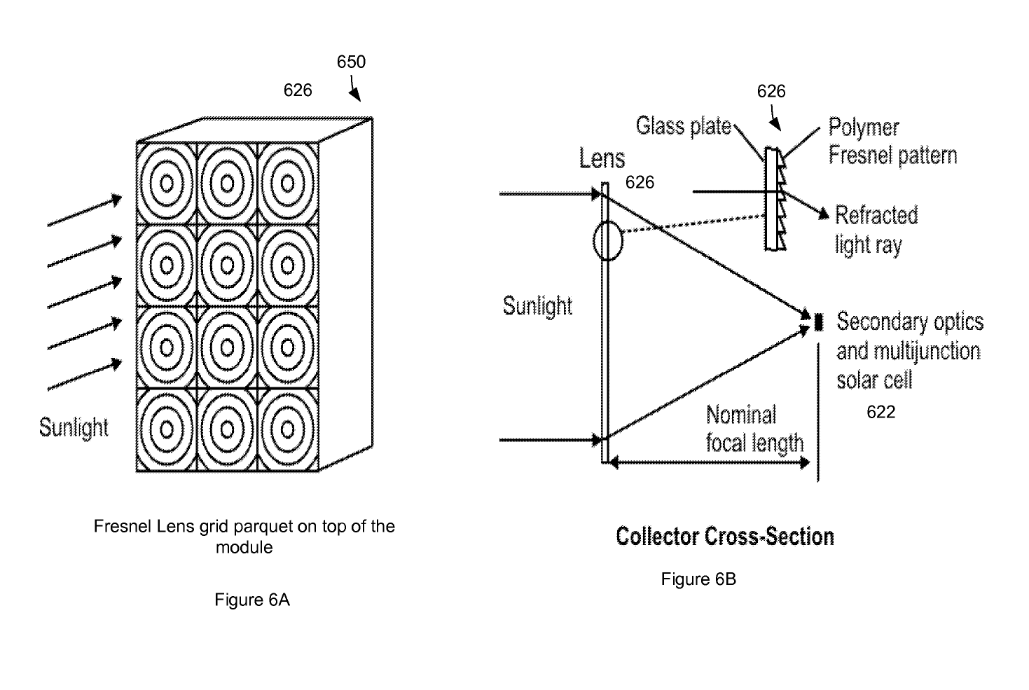

FIGS. 6A and 6B illustrate diagrams of an embodiment of a Fresnel lens optically coupling to the solar receiver. The chassis of the module 430 has an increased chassis depth from the patterned panel (parquet) with the Fresnel lenses for a focal length that optimizes efficiency and has a decreased long dimension, which fits loaded in the paddle in a shipping container. Each Fresnel lens 426 optically couples to its own secondary optic 422. The casing of the module has an increased chassis depth for focal length that optimizes optical efficiency and does not increase the depth too much to occupy too much shipping space and increase weight due to a bigger casing. The depth of the cavity balances the Fresnel focal length and angle of the pitch of the teeth of the Fresnel for efficiency of acceptance angle at least 2 mm wide focal spot across surface of secondary concentrator to hit the optically coupled photocell.

An example four concentric rings are in the ringed pattern of the Fresnel lens. A set of teeth within a given spiral/concentric ring of the ringed pattern of teeth on the Fresnel lens have 1) varying surface angles of different teeth (prisms) across the lens, 2) varying refractive indexes of the different teeth or 3) a combination of both, to establish multiple focal lengths aimed at three or more different axial target focal points within an anticipated zone of operation relative to the multiple junction photovoltaic cell in order to create the window of averaged intensity of light defined by the three or more different axial target focal points. Note, the ringed pattern of teeth may be in any number of shapes such as rasterized, spiral, concentric and other similar shapes.

Each Fresnel lens focuses light directly onto the multiple junction solar cell or via suitable secondary optic. Light enters from the top/front surface of the lens, passing through the front surface and then teeth of the lens. The Fresnel lens redirects the light rays via the set of teeth to focus the spot of the light beam on the PV cell. In another example embodiment, the Fresnel primary mirror redirects the light rays via the set of teeth to a domed shaped secondary mirror, which then reflects the concentrated beam to the walls of the trapezoidal shaped portion of the prism and onto the PV cell.

The Fresnel mirror may be formed on a glass substrate, and the ring pattern can be fabricated using standard plastic (acrylate or silicone) molding techniques. Here, the Fresnel is formed prism teeth facets on one side and a flat plano surface on the other side. This allows the use of a solid glass top layer with the teeth pattern molded into it.

Thus, a polymer Fresnel lens designed to focus all rays of a given wavelength to a given focal plane at a given temperature will exhibit different focal lengths for different wavelength, the whole focal region is shifted as temperature changes. This problem increases at high geometric concentration (1000× and above), where the focusing is tighter. Such a lens cannot effectively couple optical power to a small multi-junction photocell at any temperature, let alone over a large temperature range. The Fresnel with surface angles of different teeth set for two or more colors in the spectrum also mitigates chromatic aberration. Accordingly, the surface angles of different teeth are interleaved in each of the two or more concentric rings in the ringed pattern across the lens and are set to create at least multiple focal points for two or more colors in the visible light spectrum to define the boundaries of the window of averaged intensity of light to reduce effects of lens temperature change on the light intensity distribution of different wavelengths in the focal zone/window of averaged intensity of light defined by the multiple focal points, in order to maintain good color mixing/spot size overlap for the two or more colors, best multi-layer solar cell efficiency, and averages out light intensity distribution across the surface of the multi-layer PV solar cell.

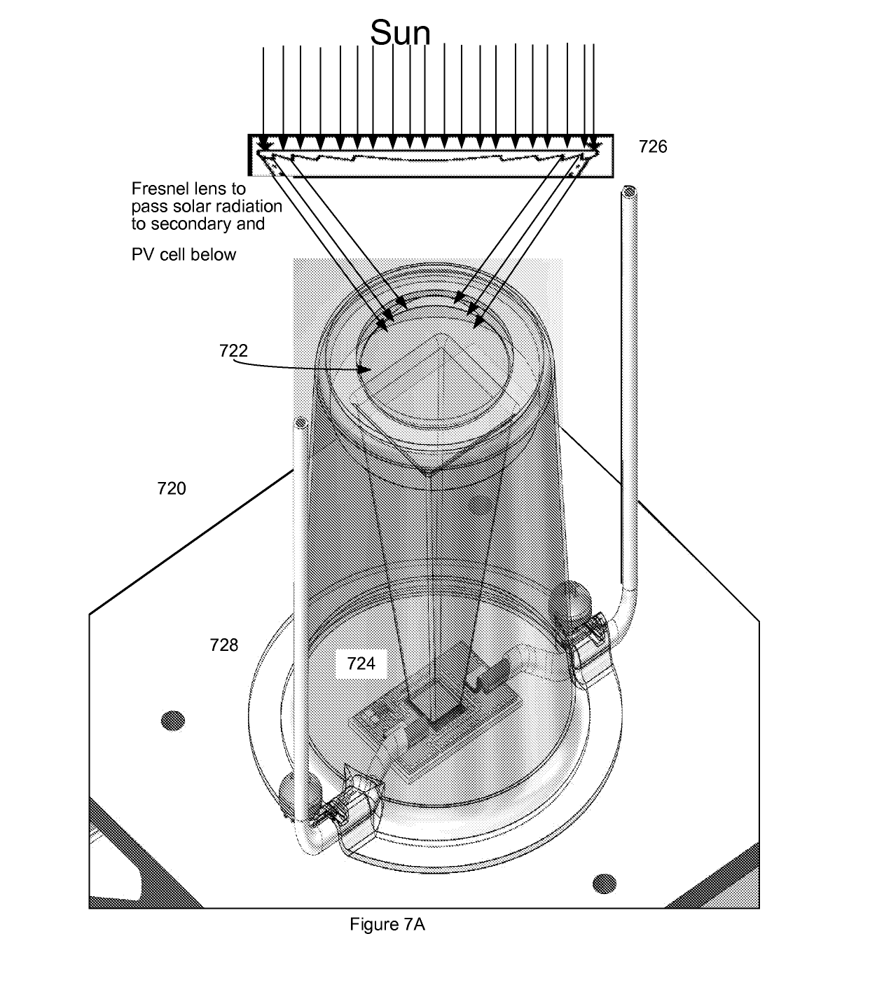

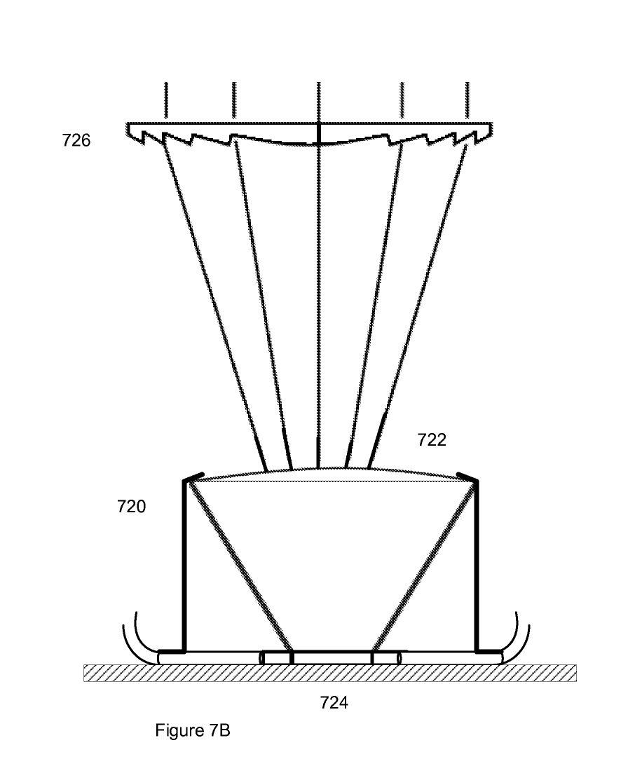

FIGS. 7A and 7B illustrate diagrams of embodiments of a total internal reflection prism having a domed shaped top portion and trapezoidal bottom portion that is used as a secondary concentrating mirror surface for the multiple junction photovoltaic cell. Referring to FIG. 7A, incident light goes through the Fresnel lens 726. The light then couples onto a secondary optic 722 of an internal reflection prism placed above the active surface of the solar cell 724 in this two-stage concentrated photovoltaic (CPV) system. The Fresnel lens 726 focuses the solar radiation to a concentrating optic coupled to the photovoltaic cell in a receiver assembly. The secondary concentrator coupled to the photovoltaic solar cell has an optical concentration of 900-1400 times, and preferably 1100 times concentration. The receiver assembly with the Fresnel lens 726 makes a CPV power unit.

The trapezoidal bottom portion of the prism has walls. The total internal reflection prism is optically coupled between the multiple junction photovoltaic cell 724 and any primary lens, for example the Fresnel lens 726 with teeth. The secondary concentrating mirror surface increases concentration in number of suns intensity impinging the cell active area of the multiple junction photovoltaic cell over the primary lens by itself. When the primary lens is the Fresnel lens 726 with teeth, the lens redirects light rays via the set of teeth to the domed shaped secondary concentrating mirror, which then reflects the concentrated beam of light to within the walls of the trapezoidal shaped portion of the prism and onto the multiple junction photovoltaic cell. The domed shaped top portion and trapezoidal bottom portion are created as a single-piece/monolithic secondary optic that provides a larger acceptance angle than the trapezoidal bottom portion by itself, while also providing good homogenization of the light intensity across the surface of the multiple junction PV cell. The larger acceptance angle of the domed shaped TIR allows a greater power out of the CPV cell for a given amount of incident sunlight put in on the Fresnel lens 726 because not all of the solar receivers across the entire paddle assembly may not at all times be perfectly pointed at the Sun.

Note, the efficiency of multi-junction cells increases with the optical power concentration ratio, reaching a maximum typically the 500 to 1000 “suns” range. The concentration in number of suns is defined as the ratio of the average intensity impinging the cell active area divided by 0.1 W/cm2.

The shape of the surface of the refractive dome is such that incident light rays that are outside the acceptance angle of the trapezoidal prism by itself are bent by the surface of the dome to enter the plane starting the trapezoidal portion to be within the acceptance angle of the trapezoidal portion and propagate to the solar PV cell to provide good homogenization, while the shape of the surface of the refractive dome kaleidoscopic prism effect for intensity homogenization and color mixing. The secondary optics with the proposed dome top and trapezoidal bottom shape employ reflection and may be implemented as solid glass or plastic bodies. The solid forms cause some refraction at the entrance face, but this is largely incidental to light propagation to the exit face. The solid forms utilize the principle of total internal reflection (TIR) at the side walls.

Referring to FIG. 7B, the Fresnel lens 726 directs light to the secondary optic to concentrate solar radiation to a photovoltaic cell in a receiver assembly. The receiver with the Fresnel lens 726 optically coupling to the photovoltaic cell may make a CPV power unit. The Fresnel lens 726 passes and directs the angle of the solar radiation to a receiver containing a secondary optic and the photovoltaic solar cell. The Fresnel lens 726 directs light to the dome of the secondary optic 720. The solar cell under the secondary prism is a multi-layer/multi-junction device designed to convert as much of the solar spectrum reaching the surface of the solar cell as feasible.

The multiple junction solar cell 724 may be properly sized to give out a desired amount of electrical power. The multiple junction photovoltaic solar cell may be properly sized between 4 to 6 millimeters squared and preferably at 5.5 meters squared. The size of the multiple junction solar cell is a tradeoff on 1) the amount of passive cooling provided by a heat sink coupled to that photovoltaic solar cell when the cell warms up to a steady state operational temperature to prevent overheating that photovoltaic solar cell and its associated lower DC voltage amount for that over heated solar cell, and 2) a limit on electron migration due to the area of the solar cell.

Thus, the photovoltaic solar cell proper size may be a balance of passive cooling by a heat sink coupled to that photovoltaic solar cell to dissipate generated heat when the cell is producing working level voltage.

The smaller in area of the size of a CPV cell, then the cost are dominated by manufacturing and assembly costs. The larger in area of the size of a CPV, then operationally a passive heat sink alone cannot remove enough heat to prevent the average temperature of the cell from overheating and lower output voltage during operation. The larger in area of the size of a CPV, then electron mobility migration becomes too big to efficiently get all of the moving electrons directed out of the CPV cell to generate DC current out and subsequently the cell loses efficiency per solar energy input. For example, a 100 MM squared cell size would have too much heat and electron mobility problems. For example, a 1 mm squared CPV cell too costly to manufacture on a per CPV cell compared to the power generated.

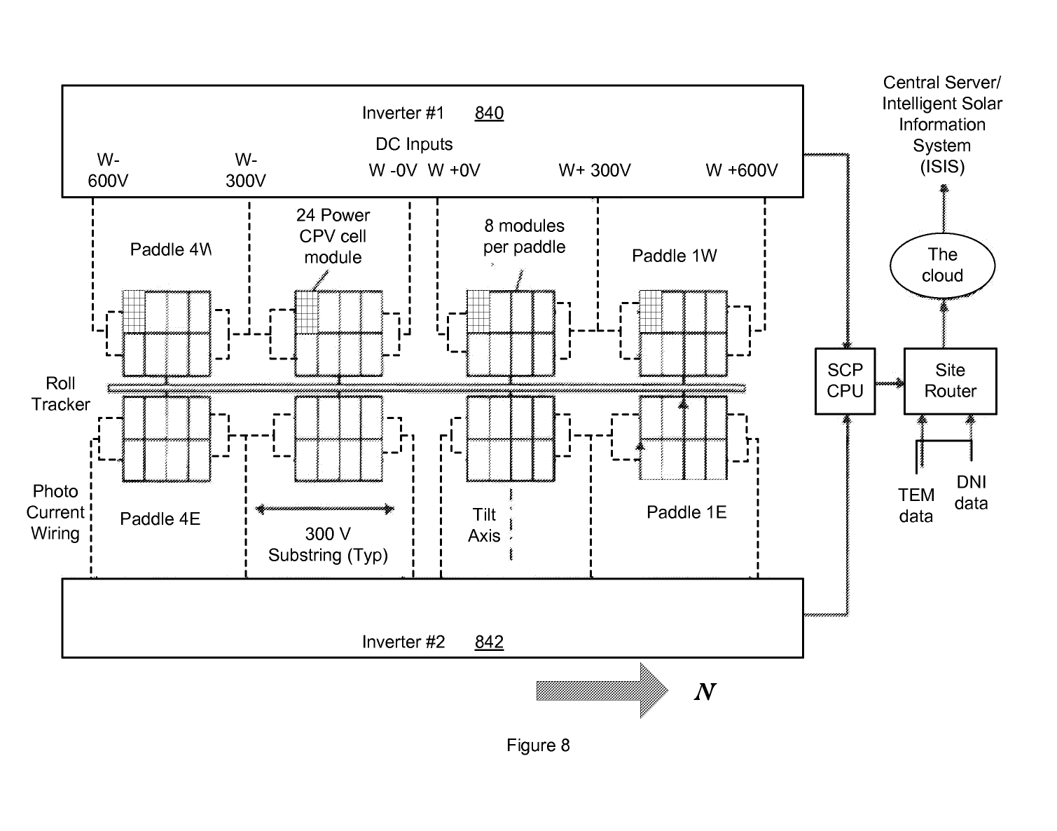

FIG. 8 illustrates a block diagram of an embodiment of the physical and electrical arrangement of modules in a representative two axis tracker assembly. In an example, set of two or more paddle pair assemblies exist per two axis tracker mechanism, and the paddle structures may each have a fixed number of CPV cells to establish a roughly fixed range of input voltage for an inverter circuit that will convert the DC voltage from the concentrated photovoltaic cells into three phase AC voltage. There may be plurality of solar power units per module such as twenty four, eight modules per paddle structure, two paddle structures forming a paddle pair assembly per tilt axis, and four independently-controlled tilt axles per common roll axle, and a bi-polar voltage from the CPV cells in the set of paddle pair assemblies may be, for example, a +600 VDC and a −600 VDC making a 1200 VDC output coming from the sixteen PV modules, where the sixteen PV module array may be a string/row of CPV cells arranged in an electrically series-parallel arrangement of two +300 VDC strings adding together to make the +600 VDC, along with two 300 VDC strings adding together to make the −600 VDC. The absolute voltage level supplied can range from an absolute 700-1200 VDC. The DC voltage level from the solar arrays is high enough to convert to the working AC voltage level such as 480 while avoiding the need for a DC boost stage. For each string of CPV cells feeding an inverter, a dynamic common reference point circuit creates a 0 volts DC reference point between paddles. Enough CPV cells are strung together so that at a working temperature even if twenty-five percent of the CPV solar cells in the string are currently shaded or inoperable, at least a minimum threshold working amount of voltage and power may still be produced by the power inverter in the integrated electronics housing for that two axis tracker assembly.

Each three phase AC Inverter circuit 840, 842 may have multiple, such as two, MPPT strings per solar array operating over a wide temperature range. The multiple modules, such as 8, may be electrically strung together to supply the two, MPPT strings of CPV cells and DC voltage to the inverters. The row of CPV cells from two or more distinct CPV modules are connected together and feed an inverter circuit. The rows are on the same horizontal plane of a module so they experience roughly the same shading effects from Sun even though they are on two distinct solar arrays.

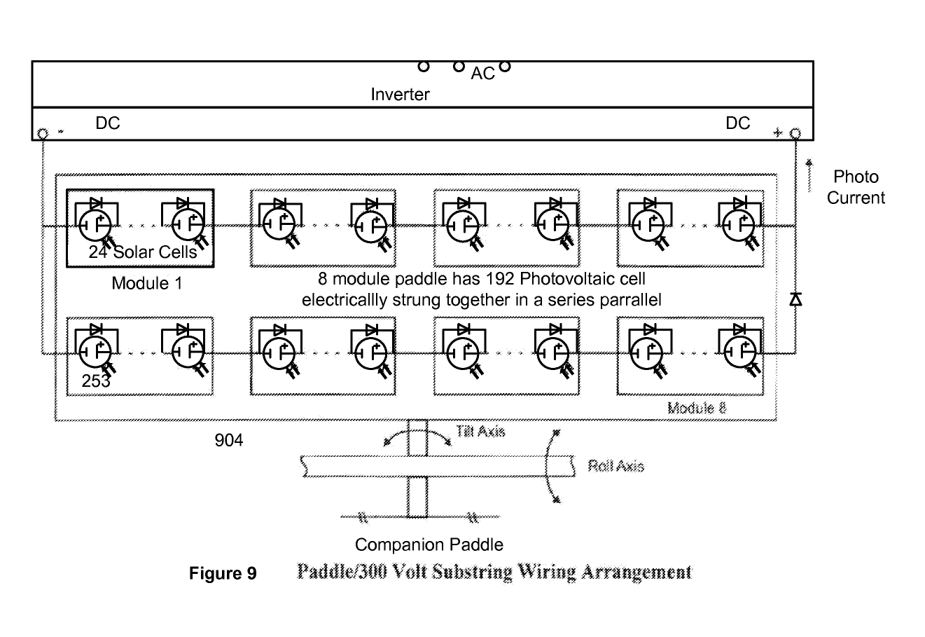

FIG. 9 illustrates a diagram of an embodiment of a paddle structure generating DC voltage by the CPV cells supplying power to an inverter power circuitry and is specifically designed to supply an input voltage range anticipated from the fixed number of photovoltaic cells, such as 192 cells. Each paddle 904 of the solar array may contain a set of CPV modules that have a fixed number of CPV cells to establish a roughly fixed range of operating voltage for the inverter. For example, it may be 8 module assemblies, in which each CPV module contains 24 individual concentrated photovoltaic cells. The ideal method of utilizing the DC output of a solar cell array is to wire enough cells in series to produce a DC voltage that is high enough to directly invert to the grid power form (480V 3 phase in the US, 400V 3 phase in the EU). This assists in eliminating the need for a DC-DC boost converter stage preceding the inverter or a voltage step-up transformer following the inverter to convert the DC to the proper AC amount.

Enough CPV cells are connected electrically in series in a string of CPV cells to allow the bipolar DC voltage from the CPV modules to allow the DC input voltage level from the CPV string of cells to be high enough to directly convert the DC voltage to the working AC voltage level but lower than the maximum DC voltage limit set by the National Electric Code, such as +/−600 VDC.

The CPV cells in each module are wired to each other within the module and has an inter-receiver connector approach performed in the manufacturing facility itself. See FIG. 7A for an example of the two wires coming from an individual CPV cell in a solar receiver. Elimination of individually wiring each of the hundreds of thousands of solar cells, such as the first CPV cell 253 through the Nth CPV cell 255, in the solar generation facility during the field installation occurs. Wiring is installed and connections are made between the CPV cells in each CPV module in the manufacturing facility itself, which eliminates individually wiring each of the fifteen hundred CPV solar cells in each solar array during the field installation. The solar cells in each module are wired in the series-parallel arrangement as shown. A bypass diode exist on each individual CPV solar cell and is electrically in parallel with that individual CPV solar cell so when that cell is being shaded or fails, the electrically series connected CPV solar cell in that CPV string does not act as a load to significantly knock down a DC voltage output from that CPV module.

One or more strings of multiple junction solar cells, such as one with a layer of GaAs, from the solar array is configured such that its highest end-to-end voltage (unloaded, cold cells) is not in excess of, 1200 Vdc, and is combined with switching devices in a safety circuit bypass so that none or just a portion of the CPV cells in the string is bypassed to ensure an instantaneous voltage of the string(s) is not in excess of, 1200 Vdc. For compliance with the +/−600 V-to-ground safety limit, the midpoint of the string is connected to utility ground via a normally closed relay contact while the inverter is off, this creating a +/−600 V bipolar string.

Note, the solar cells are multi-junction solar cells, which range of output voltage is higher than silicon based cells and which range of output voltage varies less with temperature differences than silicon based photovoltaic cells. Each string of CPV cells electrically connecting to its inverter circuit has its own MPPT sense circuit to maximize the power coming out of that string. Each MPPT has an operating window of output voltages from a string of CPV cells into the inverter of up to 600 VDC whereas most other MPPT sense circuits are limited to 480 VDC.

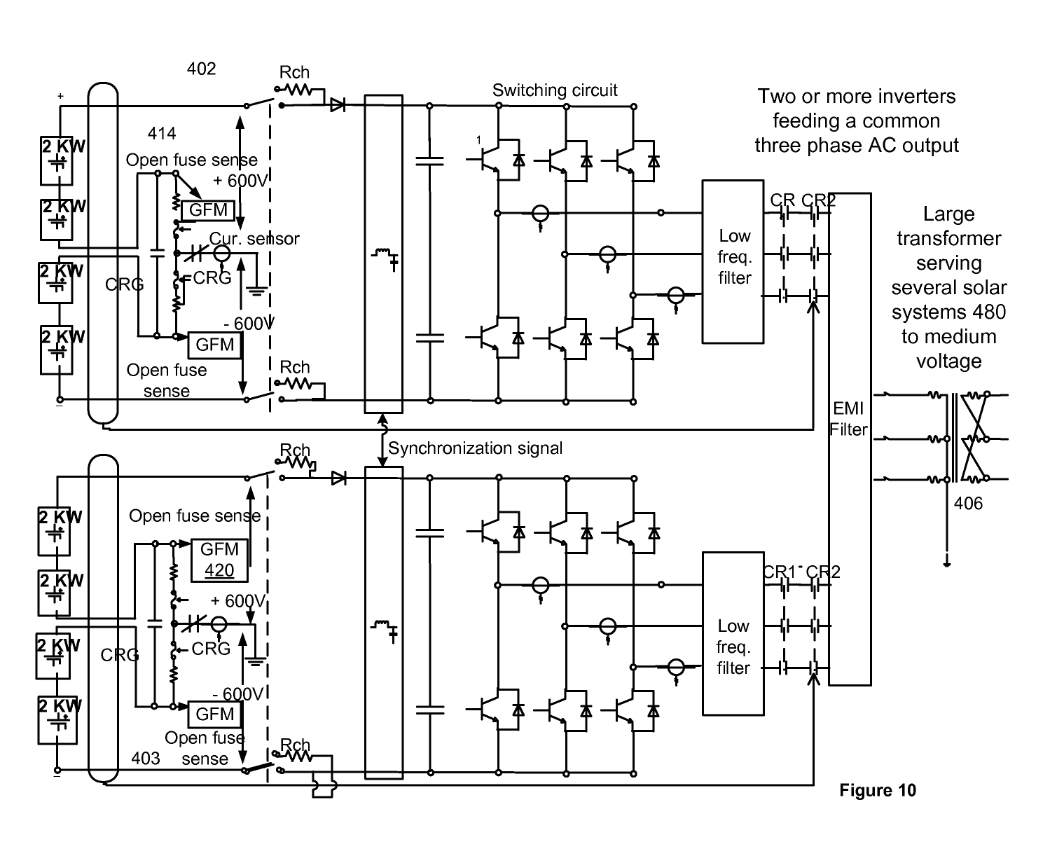

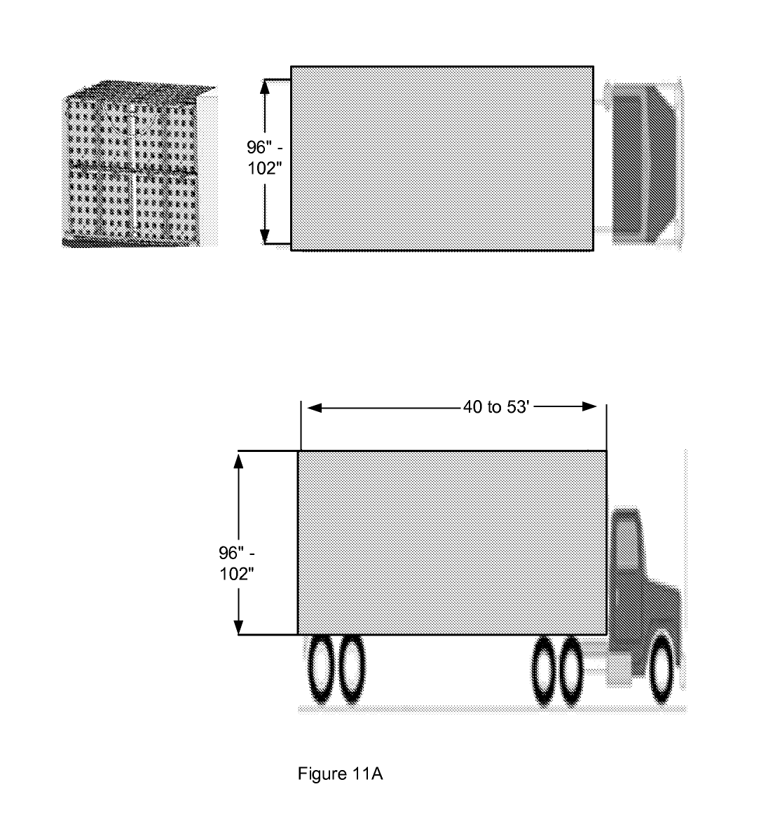

FIG. 10 illustrates a schematic diagram of an embodiment of a first AC inverter circuit and a second AC inverter circuit combining to supply the Utility Power grid transformer. The AC output of the first and second three-phase AC inverter circuits combine into a common three phase AC output, which is supplied to the Utility Power grid transformer. The first and second bipolar DC input voltage levels from the strings of CPV modules may be supplied at a high enough level to directly convert this DC input voltage level to an AC working voltage level coming out of the three-phase AC inverter circuits. One or more strings of CPV cells all from the East side of a solar array may feed into the first three-phase AC inverter circuit. Likewise, one or more strings of CPV cells all from the West side of the solar array may feed into the second inverter circuit. Each paddle designed to give 2 KW in DC power and works backward to an amount of CPV cells needed in a paddle.

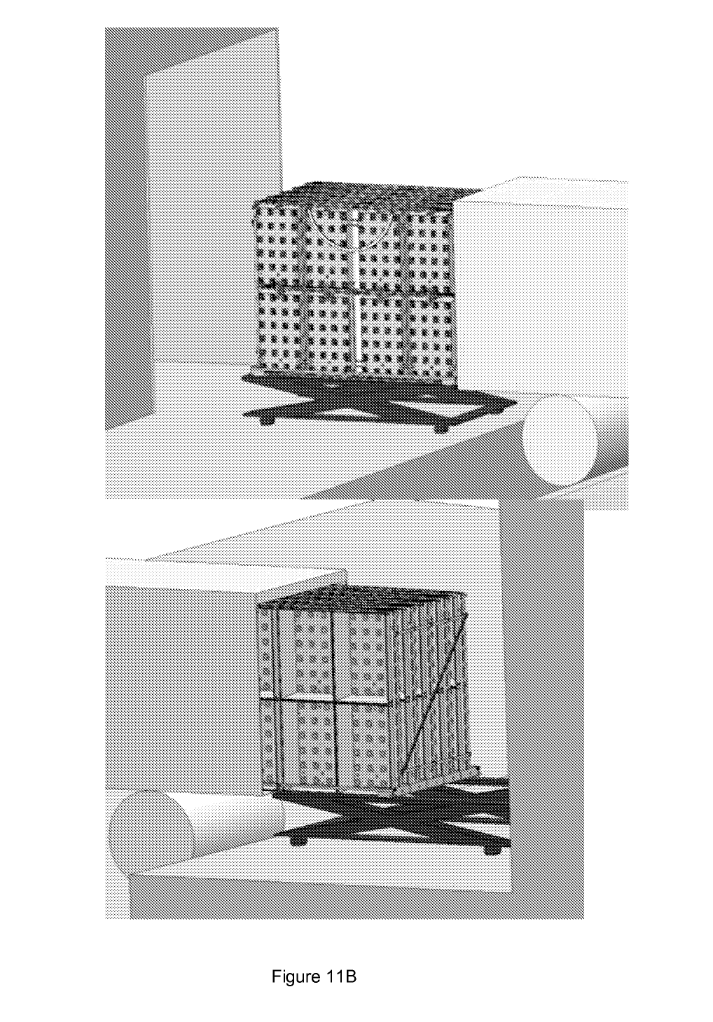

FIGS. 11A and 11B illustrate diagrams of an embodiment of paddle structures having a designed shape and dimension of the paddle structures loaded with one or modules to fit into a standard sized shipping container.

The component parts of the paddle structures and modules have been optimized for shipping both in shape, size, and dual functionality. The paddles are shipped with multiple units, such as 5, stacked together and stand vertically. Braces and bolts hold the paddles together and wrapping foil protects the paddles with their CPV modules installed. Each paddle structure has a designed shape and dimension of the paddle structures loaded with the one or modules to fit into a standard sized shipping container of at least 8 foot high by 8 foot wide and have standard lengths between 10 to 45 feet.

Although the foregoing embodiments have been described in some detail for purposes of clarity of understanding, the invention is not limited to the details provided. The Solar array may be organized into one or more paddle pairs. Functionality of circuit blocks may be implemented in hardware logic, active components including capacitors and inductors, resistors, and other similar electrical components. Flange may be replaced with couplings and similar connectors. The two-axis tracker assembly may be a multiple axis tracker assembly in three or more axes. Functionality can be configured with hardware logic, software coding, and any combination of the two. Any software coded algorithms or functions will be stored on a corresponding machine-readable medium in an executable format. There are many alternative ways of implementing the invention. The disclosed embodiments are illustrative and not restrictive.

We claim:

1. A two axis tracker mechanism with a solar array that has a surface area of the solar array structurally broken up into multiple discreet components smaller in size than an entire solar array itself, comprising:
one or more CPV modules aligned within and secured in place in each paddle structure;
multiple paddle pair assemblies per common roll axle of the two axis tracker mechanism that form and make up the surface area of the solar array, where two or more of the paddle structures form a paddle pair assembly per tilt axle of the two axis tracker mechanism and each tilt axle is independently movable from another tilt axle connected to the common roll axle;
a set of solar receivers, each with its own secondary concentrator optic, that is aligned within and secured in place in each CPV module; and
each solar receiver has its own secondary concentrator optic that focuses incident light onto its own photovoltaic cell, where all of the photovoltaic cells on the two axis tracker mechanism are electrically connected to form the voltage output from the solar array.

2. The two axis tracker mechanism of claim 1, wherein the smaller sized paddle structures facilitate getting each of the CPV solar cells in the entire solar array at a more ideal angle relative to the Sun for that solar cell, and where the paddle structure is sized between seven to nine meters squared and balanced in size for an amount of steel to support the paddle's weight verses an amount of articulation costs needed to accurately point and then maintain the CPV solar cells contained in that paddle pair assembly at the ideal angle towards the Sun.

3. The two axis tracker mechanism of claim 1, wherein the solar array is broken up into multiple smaller paddle pair assemblies with a shared mechanical interface between paddle structures in that paddle pair assembly along the tilt axis on the two sides of the common roll axle, which gives each paddle pair assembly a greater accuracy at aiming at the Sun due to 1) having less overall weight to drive the paddle pair assembly and 2) substantially an even amount of weight and wind forces felt on each side of the common roll axle in that paddle pair assembly, and thus, the weight of the paddle structures on each side of the common roll axle counter balances the paddle pair assembly making the drive motor and linear actuators mainly having to deal with wind loading effects which should roughly be about the same on both sides of the paddle pair assembly.

4. The two axis tracker mechanism of claim 1, wherein by creating structurally multiple smaller solar power generating units, each paddle structure has 1) less steel, 2) less weight, and 3) less surface area than if created as a single unitary solar array with the same aggregate surface area of all of the paddle structures making up the solar array, and with less weight and less surface area, the paddle structure is subject to less bending or bowing across an entire length of the paddle structure.

5. The two axis tracker mechanism of claim 1, wherein the paddle pair assembly is broken into two discrete parts across the common roll axle that move as one unitary larger solar surface area, so the wind then has a small space in the middle between the two paddles structures in the paddle pair assembly to pass through and minimize the wind loading effect on the paddle pair assembly.

6. The two axis tracker mechanism of claim 1, wherein a first paddle pair assembly is driven by a first tilt drive mechanism to be moved to its ideal angular coordinates in the tilt axis independent of a neighboring paddle assembly that is driven by a second tilt drive mechanism to its ideal angular coordinates in the tilt axis, where the first and second paddle pair assemblies are part of the same solar array on the two axis tracker mechanism.

7. The two axis tracker mechanism of claim 1, wherein each paddle structure contains between two to eight CPV modules as part of the solar array of the two-axis tracking mechanism, which are stamped to create rows and columns of CPV cells, and take advantage of being mass produced, and
the paddle structures have a mechanical interface between each paddle structure to structurally lock together the paddle structures to form a paddle pair assembly along the tilt axis on a tilt axle on the two sides of the common roll axle that moves in unison on the tilt axis.

8. The two axis tracker mechanism of claim 1, further comprising:
a grid of Fresnel lenses covering a casing of a first module, wherein the grid of Fresnel lenses use less material to construct than a normal convex lens and have a wider pointing angle than do conventional mirrors, and a first solar receiver unit, which contains a first secondary concentrator and a first photovoltaic cell, optically couples with a first Fresnel lens in the grid.

9. The two axis tracker mechanism of claim 1, wherein the secondary concentrator for the photovoltaic cells in the solar receiver unit has a domed secondary to give a greater acceptance angle for the solar receiver, and the secondary concentrator coupled to the photovoltaic solar cell has an optical concentration of 900-1400 times concentration.

10. The two axis tracker mechanism of claim 1, wherein the photovoltaic cells are multiple junction solar cells, and where a first Fresnel lens focuses incident Sunlight to a first secondary concentrator optically coupled to a first multiple junction photovoltaic cell, where the first secondary concentrator has a domed top portion and a trapezoidal bottom portion with walls, and where the first Fresnel lens with its teeth redirects light rays to the domed shaped secondary concentrating mirror, which then reflects the concentrated beam of light to within the walls of the trapezoidal shaped portion of the prism and onto the first multiple junction photovoltaic cell, and the domed shaped top portion and trapezoidal bottom portion provide a larger acceptance angle than the trapezoidal bottom portion by itself, while also providing good homogenization of the light intensity across the surface of the multiple junction PV cell.

11. The two axis tracker mechanism of claim 1, further comprising:
a Fresnel lens optically coupling to a first solar receiver, where a set of teeth within a given concentric ring of the ringed pattern of teeth on the Fresnel lens has 1) varying surface angles of different teeth across the lens, 2) varying refractive indexes of the different teeth or 3) a combination of both, to establish multiple focal lengths, wherein a casing of a first module has a cavity and chassis with a chassis depth for focal length that optimizes optical efficiency and substantially maintains depth in order to not occupy too much shipping space or increase weight due to a bigger casing, where the depth of the cavity balances the Fresnel focal length and angle of the pitch of the teeth of the Fresnel for efficiency of acceptance angle of the multiple focal lengths across surface of secondary concentrator.

12. The two axis tracker mechanism of claim 1, wherein the photovoltaic cells are multiple junction solar cells, and where the multiple junction photovoltaic solar cells are properly sized between four to six millimeters squared, where the size of the multiple junction photovoltaic solar cell is a tradeoff on 1) an amount of passive cooling provided by a heat sink coupled to that photovoltaic solar cell when the cell warms up to a steady state operational temperature to prevent overheating that photovoltaic solar cell and its associated lower DC voltage amount for that over heated solar cell, and 2) a limit on electron migration due to a total area of the multiple junction photovoltaic solar cell.

13. The two axis tracker mechanism of claim 1, wherein the photovoltaic cells are multiple junction solar cells, and one or more strings of multiple junction solar cells from the solar array are wired together such that its highest end-to-end voltage, unloaded, cold cells is not in excess of 1200 V DC but supplied at a high enough level to directly convert this DC input voltage level to a 480 V AC working voltage level coming out of the three-phase AC inverter circuits while avoiding the need for a DC boost stage in the three-phase AC inverter circuits.

14. The two axis tracker mechanism of claim 1, wherein string of CPV cells from the solar array is arranged in an electrically series-parallel arrangement where enough CPV cells are strung together so that at a working temperature even if twenty-five percent of the CPV solar cells in the string are currently shaded or inoperable, at least a minimum threshold working amount of voltage of 480 VAC and power can still be produced by the one or more inverter AC power circuits in the integrated electronics housing for that two axis tracker assembly.

15. The two axis tracker mechanism of claim 1, further comprising
one or more strings of CPV cells, all from the East side paddle structures of the solar array are wired to feed into a first three-phase AC inverter circuit; one or more strings of CPV cells all from the West side paddle structures of the solar array are wired to feed into a second three-phase AC inverter circuit; and
an AC output of the first three-phase AC inverter circuit and an AC output of the second three-phase AC inverter circuit combine into a common three phase AC output, which is supplied to the Utility Power grid transformer from that two axis tracker mechanism, where a first bipolar DC input voltage levels from East side strings of CPV cells is wired together from the solar array to be supplied at a high enough level to directly convert this DC input voltage level to an AC working voltage level coming out of the first three-phase AC inverter circuit but lower than the maximum DC input voltage limit set by the National Electric Code.

16. The two axis tracker mechanism of claim 1, wherein a first paddle structure with a hinged bracket allows the first paddle structure to form a paddle pair assembly, where the hinge allows the bracket to fold flat against a skeletal frame of the first paddle structure when the first paddle structure is shipped and also allows easy maneuverability when assembling the first paddle pair assembly in the field.

17. The two axis tracker mechanism of claim 1, wherein each paddle structure has a designed shape and dimension of the paddle structures loaded with the one or modules to fit into a standard sized shipping container of at least 8 foot high by 8 foot wide and have standard lengths between 10 to 45 feet.

18. A method of constructing a solar array for a two axis tracker mechanism; comprising:
structurally breaking up a surface area of the solar array into multiple discreet components smaller in size than an entire solar array itself;
aligning within and securing in place one or more modules, each module containing a set of photovoltaic cells, in each paddle structure, where two or more of the paddle structures form a paddle pair assembly;
forming multiple paddle pair assemblies to couple to a common roll axle of the two axis tracker mechanism, where the paddle pair assemblies form and make up the surface area of the solar array, where two or more of the paddle structures form a paddle pair assembly per tilt axle of the two axis tracker mechanism and each tilt axle is independently movable from another tilt axle connected to the common roll axle;
and where all of the photovoltaic cells on the two axis tracker mechanism are electrically connected to form the voltage output from the solar array.

19. A multiple axis tracker mechanism with a solar array that has a surface area of the solar array structurally broken up into multiple discreet components smaller in size than an entire solar array itself, comprising:
multiple paddle pair assemblies per common roll axle of the two axis tracker mechanism that form and make up the surface area of the solar array, where two or more of the paddle structures form a paddle pair assembly per tilt axle of the two axis tracker mechanism, and each tilt axle is independently movable from another tilt axle connected to the common roll axle and all of the paddle pair assemblies on the common roll axle move when the common roll axle rotates;
a set of solar receivers that is aligned within and secured in place in its own CPV module on a given paddle structure; and
where each solar receiver has a concentrator optic that focuses incident light onto its own photovoltaic cell, where all of the photovoltaic cells on the two axis tracker mechanism are electrically connected to form the voltage output from the solar array.
